(19) United States
(12) Patent Application Publication
(10) Pub. No.: US 2014/0284612 A1
(43) Pub. Date: Sep. 25, 2014

(54) LIGHT EMITTING DIODE AND METHOD FOR MANUFACTURING THE SAME

(71) Applicant: Hon Hai Precision Industry Co., Ltd., New Taipei (TW)

(72) Inventor: CHIH-CHEN LAI, New Taipei (TW)

(73) Assignee: Hon Hai Precision Industry Co., Ltd., New Taipei (TW)

(21) Appl. No.: 14/022,235

(22) Filed: Sep. 10, 2013

(30) Foreign Application Priority Data
Mar. 25, 2013 (TW) 102110414

(51) Int. Cl. H01L 33/24; H01L 33/00

(52) U.S. Cl. CPC H01L 33/24; H01L 33/0075
USPC 257/76; 438/29

(57) ABSTRACT

A light emitting diode includes a substrate, a first semiconductor layer, an active layer, a second semiconductor layer stacked on a face of the substrate successively, a first electrode electrically connected to the first semiconductor layer, and a second electrode electrically connected to the second semiconductor layer. The first semiconductor layer is disposed adjacent to the substrate. A plurality of nanoscale holes are defined in the face of the substrate contacting the first semiconductor layer. A method for manufacturing the light emitting diode is also provided.

### BACKGROUND

1. Technical Field

The disclosure relates to light emitting diodes (LEDs), and particularly to a light emitting diode with high light extraction efficiency and a method for manufacturing the light emitting diode.

2. Description of the Related Art

A conventional light emitting diode (LED) commonly includes an N-type semiconductor layer, an active layer and a P-type semiconductor layer. The active layer is located between the N-type semiconductor layer and the P-type semiconductor layer. In operation, a positive voltage and a negative voltage are applied respectively to the P-type semiconductor layer and the N-type semiconductor layer. Thus, cavities in the P-type semiconductor layer and electrons in the N-type semiconductor layer can enter the active layer and combine with each other to emit visible light when a bias is applied to the N-type and P-type semiconductor layers.

However, extraction efficiency of the conventional LED is low because typical semiconductor materials have higher refractive indexes than that of air. Large-angle light emitted from the active layer may be internally reflected in the LED, so that a large portion of the light emitted from the active layer remains in the LED, thereby degrading the light extraction efficiency of the LED.

Therefore, it is desirable to provide a light emitting diode and a method for manufacturing the light emitting diode which can overcome the above-described shortcomings.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting diode and a method for manufacturing the light emitting diode. Moreover, in the drawings, like reference numerals designate corresponding parts throughout the views.

FIGS. 1-9 are schematic views showing steps of a method for manufacturing a light emitting diode in accordance with one embodiment of the present disclosure.

### DETAILED DESCRIPTION

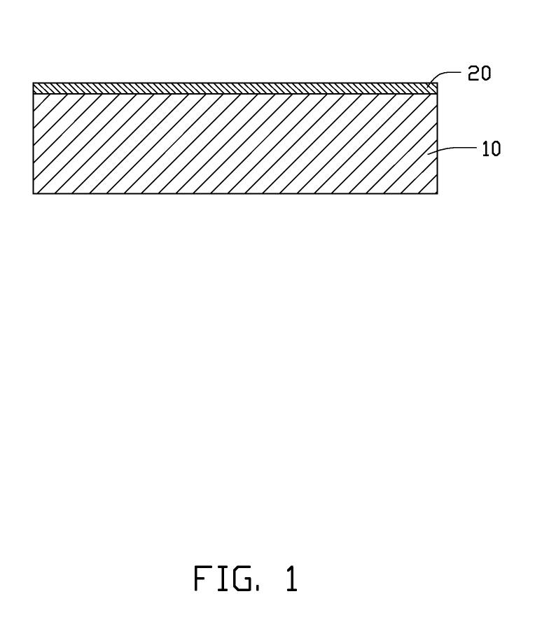

Referring to FIGS. 1-9, a method for manufacturing an LED 100 in accordance with one embodiment of the present disclosure is provided. The method for manufacturing the LED 100 includes the following steps.

Firstly, providing a substrate 10 and forming a mask 20 on a top face of the substrate 10 to cover the substrate 10 (referring to FIG. 1).

In this embodiment, the material of the substrate 10 is sapphire, and the material of the mask 20 is polysilicon. The mask 20 is formed on the top face of the substrate 10 by chemical vapor deposition (CVD). A thickness of the mask 20 is about 2 μm (micrometers).

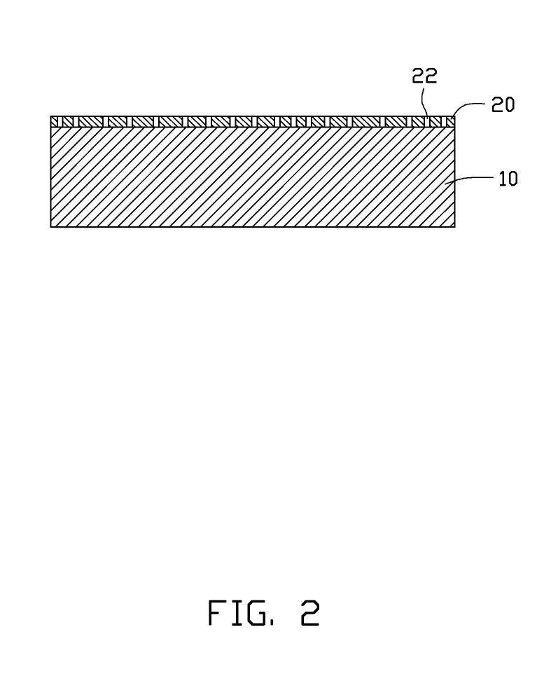

Secondly, etching the mask 20 to form a plurality of nanoscale holes 22 (referring to FIG. 2). The nanoscale holes 22 extend through the mask 20 along a thickness direction of the mask 20. Part of the top face of the substrate 10 is exposed from the nanoscale holes 22 of the mask 20.

In this embodiment, a mixed solvent of hydrofluoric acid and nitric acid is used to etch the mask 20 for about 10 to 60 minutes. The nanoscale holes 22 are dispersed in the mask 20 disorderly. A diameter of each of the nanoscale holes 22 is in a range from about 20 nm (nanometers) to about 200 nm.

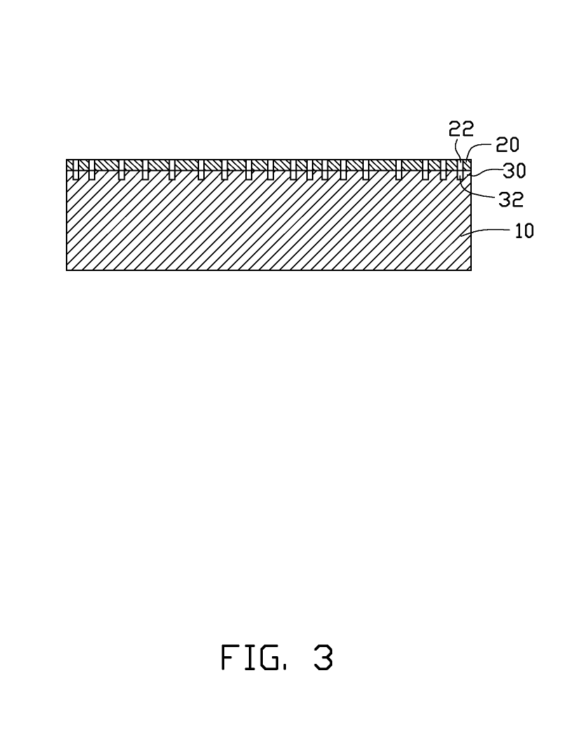

Thirdly, etching the top face of the substrate 10 through the nanoscale holes 22 of the mask 20 to form a plurality of nanoscale holes 32 (referring to FIG. 3).

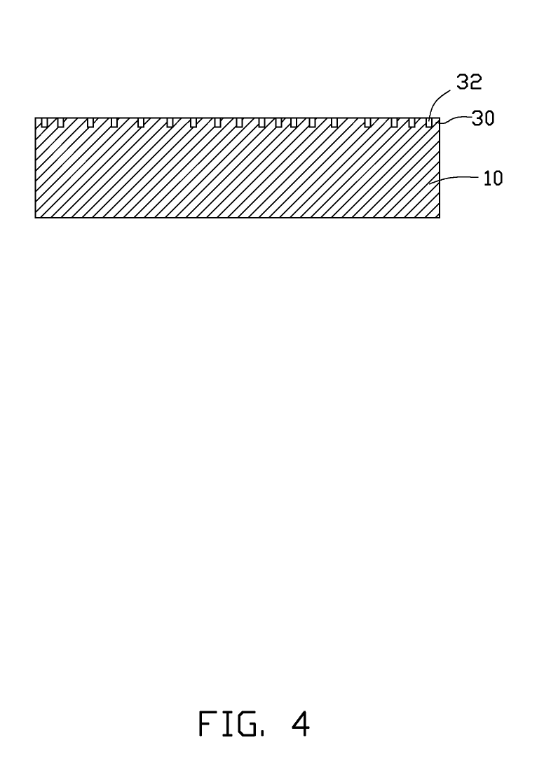

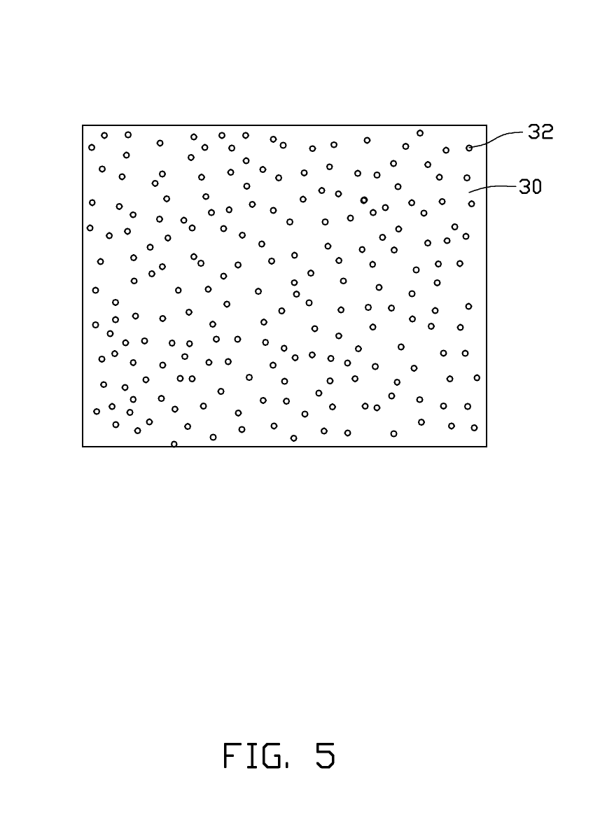

In this embodiment, the substrate 10 with the mask 20 thereon is placed in an inductively coupled plasma system, and a mixed gas of boron trichloride (BCl₃) and chlorine (Cl₂) flows through the nanoscale holes 22 of the mask 20 to etch the top face of the substrate 10. The nanoscale holes 32 are dispersed in the top face of the substrate 10 disorderly (referring to FIG. 5, FIG. 5 is a top plan view of FIG. 4). A top portion of the substrate 10 in which the nanoscale holes 32 extend acts as a scattering layer 30. A diameter of each of the nanoscale holes 32 is in a range from about 20 nm to about 200 nm.

Fourthly, removing the mask 20 (referring to FIG. 4).

In this embodiment, potassium hydroxide (KOH) solvent is used to etch and remove the mask 20.

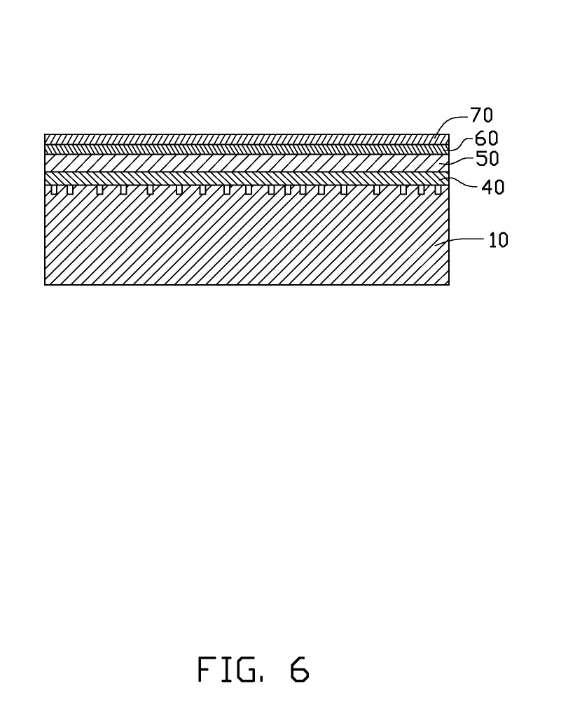

Fifthly, forming a buffer layer 40, a first semiconductor layer 50, an active layer 60 and a second semiconductor layer 70 on the top face of the substrate 10 in sequence (referring to FIG. 6).

The buffer layer 40 is sandwiched between the top face of the substrate 10 and the first semiconductor layer 50. The active layer 60 is sandwiched between the first semiconductor layer 50 and the second semiconductor layer 70. The first semiconductor layer 50, the active layer 60 and the second semiconductor layer 70 can be made of III-V or II-VI compound semiconductors. The first semiconductor layer 50 and the second semiconductor layer 70 are doped with different materials. In this embodiment, the first semiconductor layer 50 is N-type doped, and the second semiconductor layer 70 is P-type doped. In detail, the first semiconductor layer 50 is N-type GaN layer doped with Si, and the second semiconductor layer 70 is P-type GaN layer doped with Mg. In an alternative embodiment, the first semiconductor layer 50 is P-type doped, and the second semiconductor layer 70 is N-type doped.

The buffer layer 40 can reduce the lattice mismatch between the top face of the substrate 10 and the first semiconductor layer 50. Therefore, the dislocation density of the first semiconductor layer 50 will be low. In this embodiment, the material of the buffer layer 40 is GaN. A thickness of the buffer layer 40 is in a range from 80 nm to 150 nm.

The active layer 60 can be a single quantum well (SQW) structure or a multiple quantum well (MQW) structure. In this embodiment, the material of the active layer 60 is InGaN.

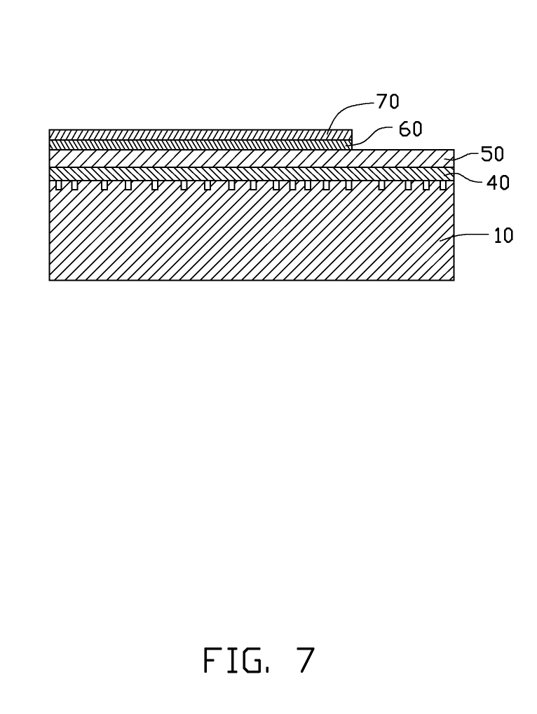

Sixthly, etching a partial portion of each of the active layer 60 and the second semiconductor layer 70 to expose a part of the first semiconductor layer 50 (referring to FIG. 7).

In this embodiment, the partial portion of each of the active layer 60 and the second semiconductor layer 70 is etched away to expose the part of the first semiconductor layer 50 by yellow light lithography technology.

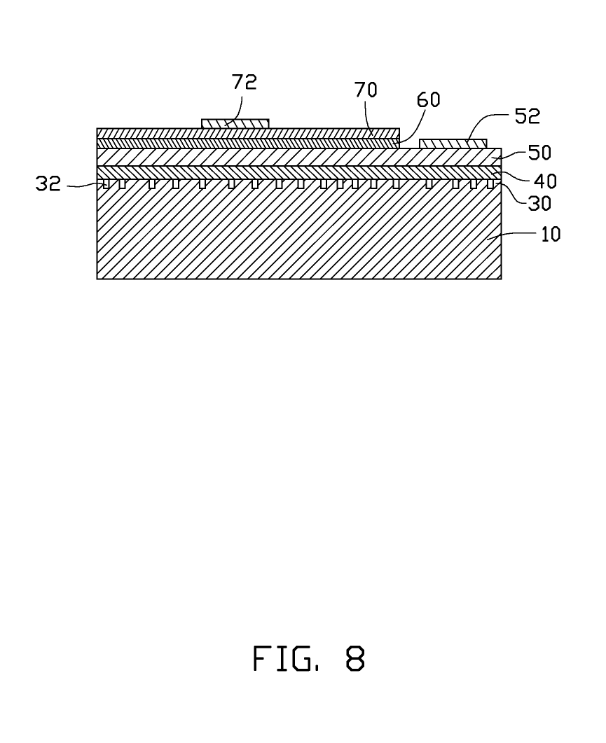

Seventhly, forming a first electrode 52 on the first semiconductor layer 50, and forming a second electrode 72 on the second semiconductor layer 70 (referring to FIG. 8).

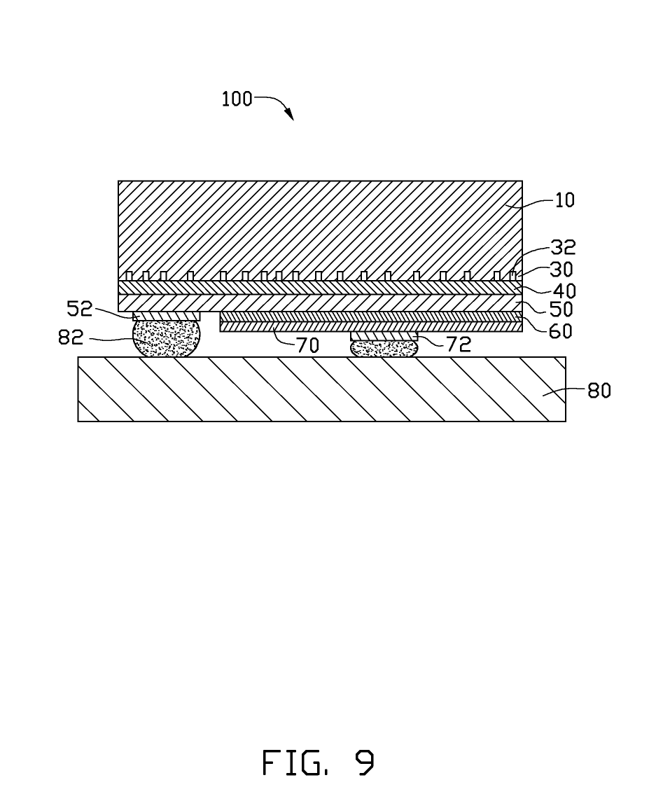

Eighthly, providing a base 80 with two spaced solders 82, and electrically connecting the first electrode 52 and the second electrode 72 with the two solders 82 on the base 80, respectively (referring to FIG. 9). Therefore, the LED 100 is achieved.

Particularly referring to FIG. 9, the LED 100 obtained by the above described manufacturing method is shown. The LED 100 includes the substrate 10, the scattering layer 30, the buffer layer 40, the first semiconductor layer 50, the active layer 60, the second semiconductor layer 70 stacked on the substrate 10 successively, the first electrode 52, the second electrode 72, the base 80 connected with the first electrode 52 and the second electrode 72 by the two solders 82. The nanoscale holes 32 extend through the scattering layer 30 along a thickness direction of the scattering layer 30. The nanoscale holes 32 are dispersed in the scattering layer 30 disorderly.

According to the disclosure, since the top face of the substrate 10 contacting the first semiconductor layer 50 defines the nanoscale holes 32, the nanoscale holes 32 can scatter light emitted from the active layer 60 and reduce the light internally reflected in the LED 100 efficiently. Therefore, the light extracting rate of the LED 100 is improved.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting diode, comprising:
a substrate;
a first semiconductor layer, an active layer, a second semiconductor layer stacked on a top face of the substrate successively, the first semiconductor layer being disposed adjacent to the substrate relative to the second semiconductor layer, a plurality of nanoscale holes being defined in the top face of the substrate contacting the first semiconductor layer;
a first electrode electrically connected to the first semiconductor layer; and
a second electrode electrically connected to the second semiconductor layer.

2. The light emitting diode of claim 1, wherein the nanoscale holes are dispersed in the top face of the substrate disorderly.

3. The light emitting diode of claim 1, wherein a diameter of each of the nanoscale holes is in a range from 20 nm to 200 nm.

4. The light emitting diode of claim 1, further comprising a base with two spaced solders, the base connecting the first electrode and the second electrode by the two solders.

5. The light emitting diode of claim 1, further comprising a buffer layer formed between the top face of the substrate and the first semiconductor layer.

6. The light emitting diode of claim 1, wherein the first semiconductor layer, the active layer and the second semiconductor layer are made of III-V or II-VI compound semiconductors.

7. The light emitting diode of claim 1, wherein the first semiconductor layer is N-type doped, and the second semiconductor layer is P-type doped.

8. The light emitting diode of claim 7, wherein the first semiconductor layer is N-type GaN layer doped with Si, and the second semiconductor layer is P-type GaN layer doped with Mg.

9. The light emitting diode of claim 1, wherein the first semiconductor layer is P-type doped, and the second semiconductor layer is N-type doped.

10. A method for manufacturing a light emitting diode comprising steps:
providing a substrate and forming a mask on a top face of the substrate to cover the substrate;
etching the mask to form a plurality of nanoscale holes, the nanoscale holes extending through the mask along a thickness direction of the mask, a part of the top face of the substrate being exposed from the nanoscale holes of the mask;
etching the top face of the substrate through the nanoscale holes of the mask to form a plurality of nanoscale holes;
removing the mask;
forming a first semiconductor layer, an active layer and a second semiconductor layer on the top face of the substrate in sequence; and
forming a first electrode on the first semiconductor layer, and forming a second electrode on the second semiconductor layer.

11. The method for manufacturing the light emitting diode of claim 10, wherein the material of the substrate is sapphire, and the material of the mask is polysilicon.

12. The method for manufacturing the light emitting diode of claim 10, wherein the mask is formed on the top face of the substrate by chemical vapor deposition (CVD).

13. The method for manufacturing the light emitting diode of claim 10, wherein a thickness of the mask is 2 μm.

14. The method for manufacturing the light emitting diode of claim 10, wherein a mixed solvent of hydrofluoric acid and nitric acid is used to etch the mask for about 10 to 60 minutes.

15. The method for manufacturing the light emitting diode of claim 10, wherein the nanoscale holes are dispersed in the mask disorderly.

16. The method for manufacturing the light emitting diode of claim 10, wherein a diameter of each of the nanoscale holes of the mask is in a range from 20 nm to 200 nm.

17. The method for manufacturing the light emitting diode of claim 10, wherein the substrate with the mask thereon is placed in an inductively coupled plasma system, and a mixed gas of boron trichloride (BCl₃) and chlorine (Cl₂) flows through the nanoscale holes of the mask to etch the top face of the substrate.

18. The method for manufacturing the light emitting diode of claim 10, wherein the nanoscale holes are dispersed in the top face of the substrate disorderly.

19. The method for manufacturing the light emitting diode of claim 10, wherein potassium hydroxide (KOH) solvent is used to etch and remove the mask.

20. The method for manufacturing the light emitting diode of claim 10, further comprising a step of forming a buffer layer between the top face of the substrate and the first semiconductor layer after the step of removing the mask.
